(19) United States
(12) Patent Application Publication
(10) Pub. No.: US 2022/0299577 A1
(43) Pub. Date: Sep. 22, 2022

(54) METHOD OF ESTIMATING INTERNAL DEGRADATION STATE OF DEGRADED CELL, AND MEASUREMENT SYSTEM

(71) Applicant: HONDA MOTOR CO., LTD., TOKYO (JP)

(72) Inventors: Shunsuke KONISHI, WAKO-SHI (JP); Seiichi KOKETSU, WAKO-SHI (JP); Hodaka TSUGE, WAKO-SHI (JP); Hidetoshi UTSUMI, WAKO-SHI (JP)

(21) Appl. No.: 17/681,816

(22) Filed: Feb. 27, 2022

(30) Foreign Application Priority Data
Mar. 18, 2021 (JP) 2021-044833

(51) Int. Cl. G01R 31/392; H01M 10/48; G01R 31/367; G01R 31/3842

(52) U.S. Cl. CPC G01R 31/392; H01M 10/48; G01R 31/367; G01R 31/3842

(57) ABSTRACT

A measurement system has a charger and an estimation apparatus and performs a method of estimating the internal degradation state of a degraded cell. The estimation apparatus calculates a reference capacity characteristic curve by differentiating a reference charge curve, sets a reference capacity characteristic curve, which is less than a division point, to a negative electrode characteristic curve, and sets a reference capacity characteristic curve, which is not less than the divisional point, to a positive electrode characteristic curve. Further, the estimation apparatus calculates a target capacity characteristic curve by differentiating the target charge curve and fits the target capacity characteristic curve and each of the negative electrode characteristic curve and the positive electrode characteristic curve, thereby obtaining changes of a plurality of types of parameters.

### CROSS-REFERENCE TO RELATED APPLICATIONS

This application is based upon and claims the benefit of priority from Japanese Patent Application No. 2021-044833 filed on Mar. 18, 2021, the contents of which are incorporated herein by reference.

### BACKGROUND OF THE INVENTION

### Field of the Invention

The present invention relates to an internal degradation state estimating method of estimating capacity degradation of a degraded cell of a secondary battery, and a measurement system.

### Description of the Related Art

JP 2015-087344 A discloses a half cell fitting method of estimating capacity degradation of a secondary battery (method of estimating an internal degradation state of a degraded cell), based on an electromotive force curve of a positive electrode and a negative electrode of the secondary battery. In the method of estimating the internal degradation state, capacity degradation is estimated based on changes of fitting parameters when the position and the shape of either one of the electromotive force curve of a new battery or the electromotive force curve of a degraded battery are changed in the capacity direction and one of the electromotive force curves is fitted to the other.

### SUMMARY OF THE INVENTION

In this regard, the method of estimating the internal degradation state of the degraded cell disclosed in JP 2015-087344 A requires that the electromotive force curve of each of the half cells (the positive electrode and the negative electrode) be obtained beforehand as reference data for comparison with a degraded battery. Conversely speaking, without no reference data, the secondary battery cannot carry out the method of estimating the internal degradation estimation state of the degraded cell.

Conventionally, the reference data of the half cells is obtained through a destructive inspection in which the secondary battery is separated (destructed) into the positive electrode and the negative electrode to perform measurements with respect to the separated positive and negative electrodes. However, the destructive inspection for estimating the capacity degradation of the secondary battery causes various problems such as inefficiency and high cost.

The present invention has been made taking the above circumstances into account, and an object of the present invention is to provide a method of estimating an internal degradation state of a degraded cell, and a measurement system in which it is possible to easily obtain reference data without performing a destructive inspection of a secondary battery, and to suitably estimate capacity degradation of the secondary battery using the reference data.

In order to achieve the above object, according to a first aspect of the present invention, a method of estimating an internal degradation state of a degraded cell is provided. The method includes obtaining a reference charge curve represented by the current capacity and the voltage for a not-yet-degraded target battery or a battery of the same type as the target battery, calculating a reference capacity characteristic curve represented by the current capacity and a derivative by differentiating the current capacity by the voltage on the reference charge curve, dividing the reference capacity characteristic curve at a division point given in the current capacity direction, and setting the reference capacity characteristic curve that is less than the division point to a negative electrode component and setting the reference capacity characteristic curve that is equal to or more than the division point to a positive electrode component, obtaining a target charge curve represented by the current capacity and the voltage for a degraded target battery, calculating a target capacity characteristic curve represented by the current capacity and the derivative by differentiating the current capacity by the voltage on the target charge curve, and estimating capacity degradation of the target battery by obtaining changes of a plurality of types of parameters based on a fitting operation that fits the target capacity characteristic curve and each of the negative electrode component and the positive electrode component of the reference capacity characteristic curve.

Further, in order to achieve the above object, according to a second aspect of the present invention, a measurement system performs a method of estimating an internal degradation state of a degraded cell is provided. The measurement system includes a charger that charges a target battery or a battery of the same type as the target battery, and an estimation apparatus connected to the charger. The estimation apparatus is configured to obtain a reference charge curve represented by the current capacity and the voltage based on charge current and charge voltage supplied to the target battery or the battery of the same type as the target battery, calculate a reference capacity characteristic curve represented by the current capacity and a derivative by differentiating the current capacity by the voltage on the reference charge curve, divide the reference capacity characteristic curve at a division point given in the current capacity direction, and set the reference capacity characteristic curve that is less than the division point to a negative electrode component and set the reference capacity characteristic curve that is equal to more than the division point to a positive electrode component, obtain a target charge curve represented by the current capacity and the voltage based on the charge current and the charge voltage supplied to the degraded target battery, calculate a target capacity characteristic curve represented by the current capacity and the derivative by differentiating the current capacity by the voltage on the target charge curve, and estimate capacity degradation of the target battery by obtaining changes of a plurality of types of parameters based on a fitting operation for fitting each of the negative electrode component and the positive electrode component of the reference capacity characteristic curve and the target capacity characteristic curve together.

In the method of estimating the internal degradation state of the degraded cell and the measurement system, it is possible to obtain the reference data without performing a destructive inspection of the secondary battery, and suitably estimate capacity degradation of the secondary battery from the reference data.

The above and other objects, features and advantages of the present invention will become more apparent from the following description when taken in conjunction with the accompanying drawings in which a preferred embodiment of the present invention is shown by way of illustrative example.

### BRIEF DESCRIPTION OF THE DRAWINGS

FIG. 1 is a diagram showing a measurement system for carrying out a method of estimating an internal degradation state of a degraded cell according to an embodiment of the present invention;

FIG. 2 is a graph showing a target charge curve of a degraded target battery and a reference charge curve represented by current capacity and voltage;

FIG. 3 is a graph illustrating factors of capacity gradation of the battery;

The left graph in FIG. 4 is a graph showing a charge curve, and the right graph in FIG. 4 is a graph showing a characteristic curve that is obtained by differentiating the current capacity by the voltage on the charge curve and is represented by the current capacity and the differential value;

FIG. 5 is a graph showing a reference capacity characteristic curve on which a division point has been set, the curve being represented by the current capacity and the differential value;

The left graph in FIG. 6 is a graph showing the reference charge curve represented by the current capacity and the voltage, and the right graph in FIG. 6 is a graph illustrating generation of a positive electrode QV curve and a negative electrode QV curve from the reference charge curve;

The left graph in FIG. 7 is a graph showing the charge curve, and the right graph in FIG. 7 is a graph showing the characteristic curve that is obtained by differentiating the current capacity by the voltage on the charge curve and is represented by the voltage and the derivative;

FIG. 8A is a flow chart showing the process flow of the method of estimating the internal degradation state of the degraded cell, and FIG. 8B is a flow chart showing the process flow of generation of the reference data; and

FIG. 9 is a flow chart showing an actual estimation process of the method of estimating the internal degradation state of the degraded cell.

### DESCRIPTION OF THE INVENTION

Hereinafter, a preferred embodiment of the present invention will be described in detail with reference to the accompanying drawings.

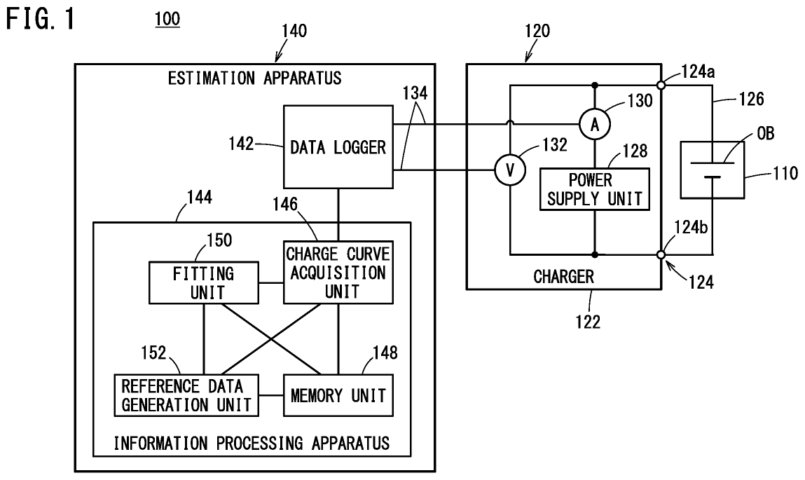

In a method of estimating the internal degradation state of a degraded cell according to an embodiment of the present invention, as shown in FIG. 1, capacity degradation of a battery as a target of measurement (hereinafter referred to as target battery OB) is estimated using a measurement system 100. The measurement system 100 includes a placement unit 110, a charger 120, and an estimation apparatus 140. The target battery OB is set to the placement unit 110. The charger 120 charges the target battery OB set on the placement unit 110. The estimation apparatus 140 is connected to the charger 120 in a manner that the estimation apparatus 140 and the charger 120 can communicate with each other, and the estimation apparatus 140 actually estimates the capacity degradation of the target battery OB.

The target battery OB has a positive electrode and a negative electrode for outputting suitable electrical power (current/voltage) and is a rechargeable secondary battery having that is rechargeable through the positive electrode and the negative electrode. The type of secondary battery is not limited and can include lithium ion secondary batteries, lithium ion polymer secondary batteries, lead acid rechargeable batteries, or nickel based rechargeable batteries, etc. This embodiment describes a case as an example where a lithium ion secondary battery is the target battery OB. The number of target batteries OB measured by the measurement system 100 is not limited to one. A plurality of target batteries OB may be measured by the measurement system 100.

The charger 120 includes a casing 122, and a pair of terminals 124 (a positive terminal 124a and a negative terminal 124b) provided for the casing 122. The pair of terminals 124 are electrically connected to the target battery OB set on the placement unit 110 through electrical wiring 126. In the casing 122 of the charger 120, are provided a power supply unit 128 capable of outputting the electric power to the pair of terminals 124, an ammeter 130 that detects charge current supplied from the power supply unit 128 to the target battery OB, and a voltmeter 132 that detects charge voltage supplied from the power supply unit 128 to the target battery OB.

The power supply unit 128 outputs suitable DC power (DC current, DC voltage) in correspondence with a state of the target battery OB. An energy storage type DC power supply capable of outputting DC power may be used as the power supply unit 128. The power supply unit 128 may have structure where the AC power supplied from the outside of the charger 120 is converted into the DC power. The ammeter 130 is connected in serial to the power supply unit 128 and detects the charge current outputted from the power supply unit 128. The voltmeter 132 is connected in parallel to the power supply unit 128 and the ammeter 130 and detects the charge voltage (inter-terminal voltage) of the target battery OB.

The estimation apparatus 140 includes a data logger 142 (memory device) connected to the charger 120 and an information processing apparatus 144 connected to the data logger 142. The data logger 142 is connected to the ammeter 130 and the voltmeter 132 of the charger 120 in a manner that the data logger 142 can communicate with the ammeter 130 and the voltmeter 132. The data logger 142 is a storage device that obtains and stores the charge current detected by the ammeter 130 and the charge voltage detected by the voltmeter 132. A known hard disk drive (HDD), a solid state drive (SSD), or an offline storage of any other type, etc. may be used as the data logger 142. Though not shown, the data logger 142 includes an input/output interface, a processor, a timer, etc. (omitted in the drawings). The input/output interface is connected to the ammeter 130, the voltmeter 132, and the information processing apparatus 144 through communication lines 134 in a manner that the input/output interface can communicate with the ammeter 130, the voltmeter 132, and the information processing apparatus 144. The processor controls writing, reading, and deletion of the charge current and the charge voltage. The charger 120 may be provided with the data logger 142. The data logger 142 may receive the charge current and/or the charge voltage from the charger 120 through wireless communication.

The data logger 142 measures time with a timer. The data logger 142 obtains the charge current and the charge voltage from the charger 120 periodically and continuously, and associates the charge current and the charge voltage with the time and accumulates them. In this manner, it is possible to form a charge curve (charge characteristics, QV curve) represented by the current capacity (mAh) and the charge voltage (V) of the target battery OB.

The information processing apparatus 144 includes at least one processor, memory, input/output interface, and electronic circuit. Various types of drives (HDD, SSD, etc.) can be used as the memory, or the memory may include the memory accompanying a processor or an integrated circuit. The at least one processor executes programs (not shown) stored in the memory, whereby a plurality of function blocks for performing information processing are formed in the information processing apparatus 144. At least some of the function blocks may be constituted by electronic circuits including discrete devices and integrated circuits such as ASIC (Application Specific Integrated Circuit) and FPGA (Field Programmable Gate Array).

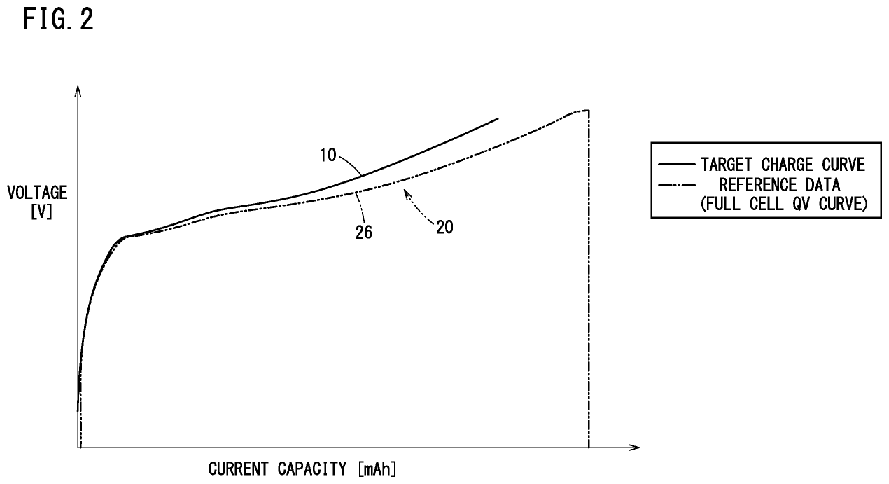

Specifically, a charge curve acquisition unit 146, a memory unit 148, a fitting unit 150, and a reference data generation unit 152 are formed as the function blocks in the information processing apparatus 144. The charge curve acquisition unit 146 obtains the charge current, the charge voltage, the time, etc. accumulated in the data logger 142, and calculates a charge curve (hereinafter, “target charge curve 10”) of the target battery OB (see FIG. 2). The target charge curve 10 represents the change of the voltage relative the current capacity at the time of charging the target battery OB. The target charge curve 10 can be shown as a graph where the horizontal axis represents the current capacity and the vertical axis represents the voltage.

As shown in FIGS. 1 and 2, known methods may be adopted for calculation of the target charge curve 10. As an example, the charge curve acquisition unit 146 calculates accumulated charge current based on the charge current, time etc. of the case where the target battery OB having the charge SOC (State of Charge) is 0% is fully charged (SOC=100%) by the charger 120. This accumulated charge current corresponds to the current capacity. The charge curve acquisition unit 146 plots the charge voltage in correspondence with the increase in the accumulated charge current. In this manner, it is possible to obtain the target charge curve 10. The charge curve acquisition unit 146 stores the target charge curve 10 (or a plurality of plots associating the current capacity and the charge voltage of the target charge curve 10 with each other) in the memory unit 148. The measurement system 100 may calculate the target charge curve 10 with the data logger 142 and transmit the target charge curve 10 to the information processing apparatus 144.

The memory unit 148 stores reference data beforehand for carrying out the method of estimating the internal gradation state of degraded cells in addition to the target charge curve 10 obtained from the charge curve acquisition unit 146. In the embodiment of the present invention, a reference charge curve 20 may be used as the reference data. The reference charge curve 20 is data obtained by the measurement system 100 performing a reference data acquisition process on a not-yet-degraded target battery OB or a battery of the same type as the target battery OB (battery produced through the same method as the target battery OB).

The fitting unit 150 performs a fitting operation of fitting information regarding the target charge curve 10 stored in the memory unit 148 and the reference data (reference charge curve 20) to estimate the capacity degradation of the target battery OB. Hereinafter, the factors of the capacity degradation of the battery, and the details of the fitting operation will be described.

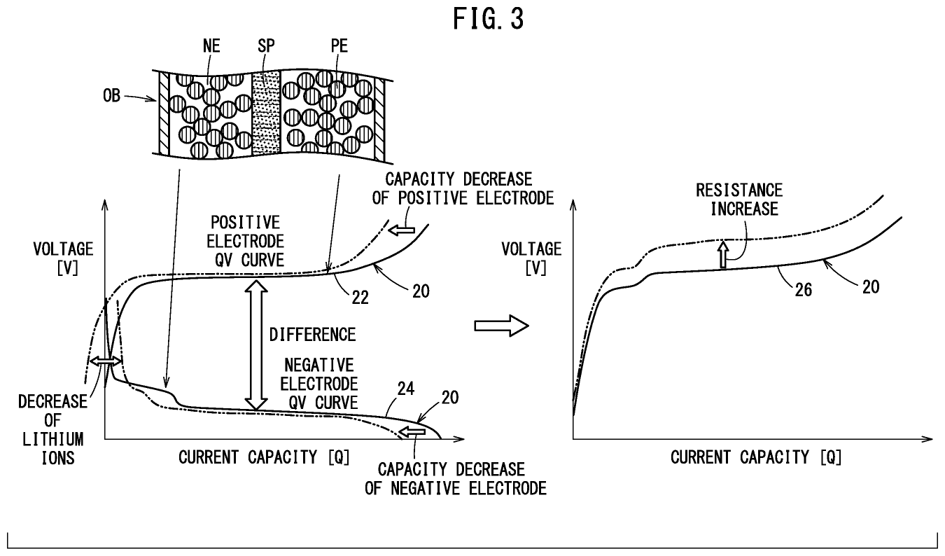

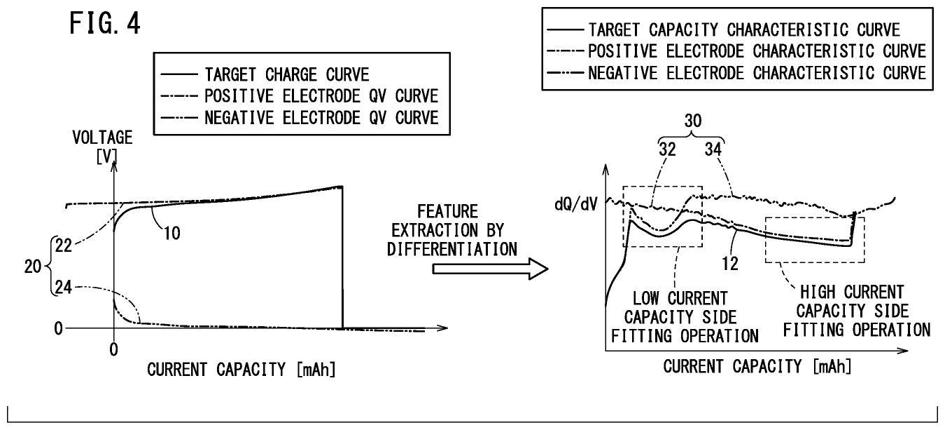

As shown in the left graph of FIG. 3, the secondary battery (lithium ion secondary battery) has a QV curve for each of the positive electrode PE and the negative electrode NE (hereinafter referred to as the positive electrode QV curve 22, the negative electrode QV curve 24). The positive electrode QV curve 22 is represented by a graph where the horizontal axis represents the current capacity (Q) and the vertical axis represents the voltage (V). The positive electrode QV curve 22 shows that after the voltage increases sharply at lower current capacities, even if the current capacity increases, the voltage remains substantially constant, and at higher current capacities, the increase rate of the voltage increases. On the other hand, the negative electrode QV curve 24 shows that after the voltage decreases sharply when the current capacity is low, even if the current capacity increases, the voltage remains substantially constant, and when the current capacity increases further toward a high current capacity, the decrease rate of the voltage increases gradually. Further, as shown in the right graph of FIG. 3, the difference between the positive electrode QV curve 22 and the negative electrode QV curve 24 becomes a charge curve between the electrodes of the secondary battery. The charge curve between the electrodes shown in the right graph of FIG. 3 will be referred to as a full cell QV curve 26 in a sense that the fuel cell QV curve 26 is a curve that has combined the positive electrode PE and the negative electrode NE, which are half cells.

In this regard, the capacity degradation of the secondary battery is caused by the following four factors, and each of the factors appears in the positive electrode QV curve 22, the negative electrode QV curve 24 and the full cell QV curve 26. In FIG. 3, changes of the positive electrode QV curve 22, the negative electrode QV curve 24, and the full cell QV curve 26 are illustrated by two dot chain lines.

(1) Capacity decrease of the positive electrode PE→decrease of the positive electrode QV curve 22 in the low current capacity direction.
(2) Capacity decrease of the negative electrode NE→decrease of the negative electrode QV curve 24 in the low current capacity direction.
(3) Decrease of the lithium ions→gap between the positive electrode QV curve 22 and the negative electrode QV curve 24 in the current capacity direction.
(4) Resistance increase→separation of the positive electrode QV curve 22 and the negative electrode QV curve 24 in the voltage direction=voltage offset of the full cell QV curve 26.

That is, the capacity degradation of the secondary battery have four parameters (the capacity decrease of the positive electrode PE, the capacity decrease of the negative electrode NE, the decrease of lithium ions, and the resistance increase).

In the conventional half cell fitting method, the positive electrode QV curve 22 and the negative electrode QV curve 24 that are the reference data are obtained by dividing (destructing) a referential secondary battery into the positive electrode PE and the negative electrode NE with a separator SP being a base point, attaching Li foil to division surfaces of the positive electrode PE and the negative electrode NE, thereafter carrying out charging, and monitoring the charge current and the charge voltage during the charging. However, operations of the destructive inspection become a factor in the lowering efficiency of the method of estimating the internal degradation state of the degraded cell.

Under the circumstances, in the method of estimating the internal degradation state of the degraded cell according to the embodiment of the present invention, before a measurement of the degraded target battery OB (actual estimation process) is performed, the reference data acquisition process of obtaining the reference data is performed using the not-yet-degraded target battery OB or a battery of the same type as the target battery OB. In the reference data acquisition process, the measurement system 100 charges the not-yet-degraded target battery OB or the battery of the same type as the target battery OB, and stores the charge current and the charge voltage during the charging in the data logger 142. Then, the information processing apparatus 144 calculates the reference charge curve 20 (full cell QV curve 26) that is the reference data, based on the charge current and the charge voltage stored in the data logger 142 (see also FIG. 2).

Further, in the reference data acquisition process, the reference data generation unit 152 of the information processing apparatus 144 divides the reference charge curve 20 into a region indicating characteristics of the positive electrode PE and a region indicating characteristics of the negative electrode NE. Division of the reference charge curve 20 will be described in detail later.

Then, in the actual estimation process, a fitting operation of matching the reference charge curve 20 (including the divided curves) obtained in the reference data acquisition process with the target charge curve 10 is performed, and the capacity degradation of the target battery OB is analyzed based on a variation amount of each of the parameters in this fitting operation. As can be seen from the relationship between the charge curves (the positive electrode QV curve 22, the negative electrode QV curve 24, and the full cell QV curve 26) and the four parameters, these parameters are in a state of being linked with each other on the charge curves.

Therefore, in the method of estimating the internal degradation state of the degraded cell according to the embodiment of the present invention, the fitting unit 150 extracts feature points of a shape of the target charge curve 10, by differentiating the current capacity with respect to the voltage on the target charge curve 10. That is, as shown in the left graph of FIG. 4, the target charge curve 10 represented by the current capacity and the voltage is converted into a characteristic curve represented by the current capacity and a derivative (dQ/dV). Hereinafter, this characteristic curve will be referred to as the target capacity characteristic curve 12. The right graph of FIG. 4 shows the target capacity characteristic curve 12 where the horizontal axis represents the current capacity and the vertical axis represents the derivative.

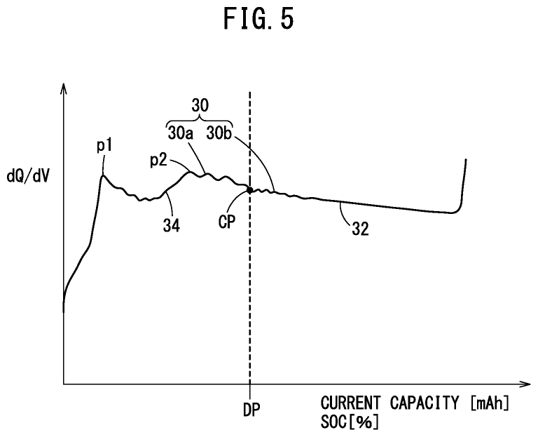

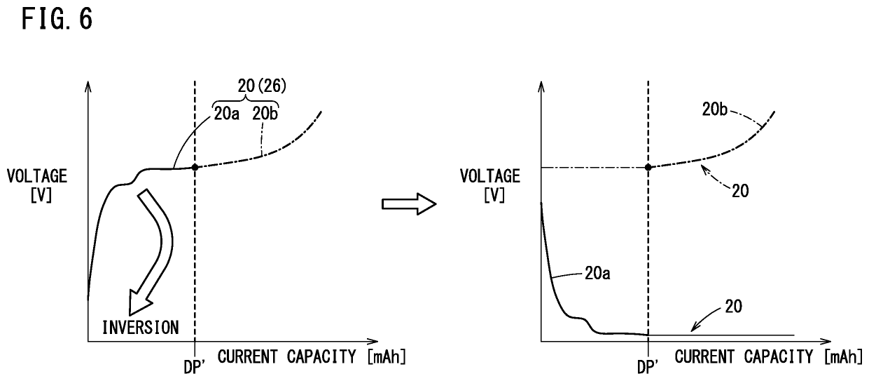

Further, in the same manner as the differentiation of the target charge curve 10, the fitting unit 150 differentiates the current capacity with respect to the voltage on (full cell QV curve 26) and as shown in FIG. 5, the fitting unit 150 converts the reference charge curve 20 into a characteristic curve (hereinafter referred to as the reference capacity characteristic data 30) represented by the current capacity and the derivative. Then, the fitting unit 150 performs a fitting operation of the converted target capacity characteristic curve 12 and the reference capacity characteristic curve 30. In this manner, it becomes possible to temporarily disregard the parameter of the resistance increase (voltage offset) during the fitting operation.

In a graph of FIG. 5, the derivative of the target capacity characteristic curve 12 has two peaks p1, p2 on the low current capacity (low SOC) side, and beyond two peaks p1, p2 in the direction in which the current capacity increases, the derivative gradually decreases as the current capacity increases. Next, correlation between the shape of the target capacity characteristic curve 12 and the shapes of the positive electrode PE and the negative electrode NE of the battery will be described.

With regard to the positive electrode QV curve 22, a characteristic curve (hereinafter referred to as the positive electrode characteristic curve 32) obtained by differentiating the current capacity with respect to the voltage has a shape shown with one dot chain line in the right graph of FIG. 4. Further, with regard to the negative electrode QV curve 24, a characteristics curve (hereinafter referred to as the negative electrode characteristic curve 34) obtained by differentiating the current capacity with respect to the voltage has a shape shown with a two dot chain line in the right graph of FIG. 4.

When the target capacity characteristic curve 12, the positive electrode characteristic curve 32, and the negative electrode characteristic curve 34 are compared with each other, it can be seen that, on the low current capacity side, the shape of the target capacity characteristic curve 12 and the shape of the negative electrode characteristic curve 34 are similar to each other. That is, on the low current capacity side, the target capacity characteristic curve 12 shows a strong correlation with the negative electrode characteristic curve 34. Conversely, on the high current capacity (high SOC) side, it can be seen that the shape of the target capacity characteristic curve 12 and the shape of the positive electrode characteristic curve 32 are similar to each other. That is, on the high current capacity side, the target capacity characteristic curve 12 shows a strong correlation with the positive electrode characteristic curve 32.

Further, as to the lithium ion secondary battery, the correlation between the target capacity characteristic curve 12 and the negative electrode characteristic curve 34 on the low current capacity side is stronger than the correlation between the target capacity characteristic curve 12 and the positive electrode characteristic curve 32 on the high current capacity side. The target capacity characteristic curve 12 and the negative electrode characteristic curve 34 on the low current capacity side have two peaks p1, p2. It can be said that between the two peaks p1, p2, the parameter of the capacity decrease of the positive electrode PE exerts is almost no influence. Stated otherwise, on the low current capacity side, the parameter of the capacity decrease of the negative electrode NE is highly independent of other parameters. On the other hand, the target capacity characteristic curve 12 and the positive electrode characteristic curve 32 on the high current capacity side do not have any clear peaks and are slightly affected by the parameter of the capacity decrease of the negative electrode NE.

In the reference data acquisition process, as described above, while the reference charge curve 20 is obtained, the positive electrode QV curve 22 as the charge curve of the positive electrode PE and the negative electrode QV curve 24 as the charge curve of the negative electrode NE are not obtained. Therefore, as shown in FIG. 5, the reference data generation unit 152 calculates the reference capacity characteristic curve 30 from the reference charge curve 20 and divides the reference capacity characteristic curve 30 at the division point DP, thereby utilizing the divided curves as an approximate positive electrode characteristic curve 32 and an approximate negative electrode characteristic curve 34.

Specifically, in the direction in which the current capacity of the reference capacity characteristic curve 30 increases (direction of the X axis), the reference data generation unit 152 sets the division point DP at a predetermined position beyond the two peaks p1, p2. For example, the division point DP is set to an inflection point CP of gradients according to which the reference capacity characteristic curve 30 decreases from the peak p2, which has a higher current capacity between the two peaks p1 and p2. The predetermined position of the division point DP is not limited specifically but in the case where the current capacity direction of the battery is converted into the SOC, preferably, the position is approximately in the range of 30% to 50% in the SOC. More preferably, the division point DP is set to a position away from the peak p2 having the higher current capacity, by 5% to 20% in the SOC in the direction in which the current capacity increases. Alternatively, the division point DP may be set at the peak p2 having the higher current capacity on the reference capacity characteristic curve 30.

By setting the division point DP as described above, it is possible to reliably identify the positions of two peaks p1, p2, which are the characteristics of the negative electrode NE in the capacity direction of the reference capacity characteristic curve 30. That is, a reference capacity characteristic curve 30a for the current capacity less than the division point DP can reproduce the characteristics of the negative electrode characteristic curve 34 whereas a reference capacity characteristic curve 30b for the current capacity equal to or more than the division point DP can reproduce the characteristics of the positive electrode characteristic curve 32.

Hereinafter, the principle of dividing the reference charge curve 20 obtained as the reference data will be described. As shown in FIG. 6, in the QV graph of the reference charge curve 20, it is possible to set a positive/negative electrode division point DP′ that divides characteristics of the positive electrode PE and characteristics of the negative electrode NE at a predetermined position in the current capacity direction (position corresponding to the division point DP in the characteristic graph of the current capacity and the differential value). When the reference charge curve 20a that is less than the positive/negative electrode division point DP′ (on the low current capacity side) is inverted in the voltage direction, it can be seen that the inverted reference charge curve 20a looks like the above described negative electrode QV curve 24 (see FIG. 3) on the low current capacity side because the low current capacity side of the reference charge curve 20 is affected by the structure of the negative electrode NE (graphite structure in the case of the lithium ion battery). Likewise, it can be seen that the reference charge curve 20b that is equal to or more than the positive/negative electrode division point DP′ (high current capacity side) looks like the above described positive electrode QV curve 22 (see FIG. 3) because the high current capacity side of the reference charge curve 20 is affected by the structure of the positive electrode PE.

The inverted reference charge curve 20a, which is less than the positive/negative electrode division point DP′, takes the same shape as the reference capacity characteristic curve 30a (see FIG. 5), which is less than the division point DP, by differentiating the current capacity with the voltage. Likewise, by taking the derivative of the current capacity with respect to the voltage, the reference charge curve 20b, which is equal to or more than the positive/negative electrode division point DP′, take the same shape as the reference capacity characteristic curve 30b (see FIG. 5), which is equal to or more than the division point DP.

In view of the above, as shown in FIG. 5, the fitting unit 150 uses the reference capacity characteristic curve 30a, which is less than the division point DP, as the negative electrode characteristic curve 34 for a fitting operation of the target capacity characteristic curve 12 on the low current capacity side. On the other hand, the fitting unit 150 uses the reference capacity characteristic curve 30b, which is equal to or more than the division point DP, as the positive electrode characteristic curve 32 for a fitting operation of the target capacity characteristic curve 12 on the high current capacity side.

Referring back to FIG. 4, the fitting unit 150 performs a fitting operation of fitting, in the order of strong correlations, the positions of the target capacity characteristic curve 12 of the target batter OB, and the positive electrode characteristic curve 32 (reference capacity characteristic curve 30b) and the negative electrode characteristic curve 34 (reference capacity characteristic curve 30a). Specifically, the fitting unit 150 first performs a low current capacity side fitting operation of fitting the target capacity characteristic curve 12 and the negative electrode characteristic curve 34 (reference capacity characteristic curve 30a) to each other on the low current capacity side. In the low current capacity side fitting operation, either one of the target capacity characteristic curve 12 or the negative electrode characteristic curve 34 is moved in the voltage direction to eliminate a gap in the voltage direction. In this manner, the parameter of the capacity decrease of the negative electrode NE is substantially adjusted.

Next, the fitting unit 150 performs a high current capacity side fitting operation of fitting the target capacity characteristic curve 12 and the positive electrode characteristic curve 32 (reference capacity characteristic curve 30b produced by differentiating the reference charge curve 20) to each other on the high current capacity side. In the high current capacity side fitting operation, whichever of the target capacity characteristic curve 12 or the reference charge curve 20 has been moved in the low current capacity side fitting operation is moved in the voltage direction to eliminate a gap in the voltage direction. In this manner, the parameter of the capacity decrease of the positive electrode PE is substantially adjusted. Further, in the high current capacity side fitting operation, whichever of the target capacity characteristic curve 12 or the reference charge curve 20 has been moved in the low current capacity side fitting operation is moved in the current capacity direction to eliminate a gap in the current capacity direction. In this manner, the parameter of the decrease of lithium ions is substantially adjusted.

That is, in the method of estimating the internal degradation state of the degraded cell, the low current capacity side fitting operation is performed before the high current capacity side fitting operation, whereby it is possible to provisionally fix the parameter of the capacity decrease of the negative electrode NE. Further, in the method of estimating the internal degradation state of the degraded cell, by performing the high current capacity side fitting operation, in the state where the parameter of the capacity decrease of the negative electrode NE is provisionally fixed, it is possible to stably adjust both of the parameter of the capacity decrease of the positive electrode PE and the parameter of the decrease of the lithium ions.

Further, the fitting unit 150 performs a voltage fitting operation of adjusting the parameter of the resistance increase (voltage offset), which has been disregarded in the low current capacity side fitting operation and the high current capacity side fitting operation. In this case, as shown in FIG. 7, the fitting unit 150 differentiates the current capacity with respect to voltage on the target charge curve 10 of the target battery OB and converts the target charge curve 10 into a characteristic curve (hereinafter referred to as the target voltage characteristic curve 14) represented by the voltage and the derivative. Accordingly, the fitting unit 150 differentiates the current capacity with respect to the voltage on the full cell QV curve 26 that is the reference charge curve 20 and converts the full cell QV curve 26 into a characteristic curve represented by the voltage and the derivative (hereinafter referred to as a full cell characteristic curve 42).

Stated otherwise, concerning the parameter of resistance increase that changes in the Y axis direction (voltage direction) for the target voltage characteristic curve 14 and the full cell characteristic curve 42, the fitting unit 150 converts the voltage direction into the X axis direction as shown in the right graph of FIG. 7 while extracting feature points of the shape of the curves by differentiation. The correlation between the target voltage characteristic curve 14 and the full cell characteristic curve 42 is weaker than the correlation between the target capacity characteristic curve 12 and the negative electrode characteristic curve 34 and the correlation between the target capacity characteristic curve 12 and the positive electrode characteristic curve 32. It is because, as described above, the full cell QV curve 26 is calculated from the difference between the positive electrode QV curve 22 and the negative electrode QV curve 24 and is easily affected by the parameters of the capacity decrease of the positive electrode PE, the capacity decrease of the negative electrode NE, and the decrease of lithium ions.

Therefore, in the voltage fitting operation, whichever of the target voltage characteristic curve 14 or the full cell characteristic curve 42 (reference charge curve 20) has been moved in the high current capacity side fitting operation is moved in the voltage direction (X axis direction) to eliminate a gap in the voltage direction. In this manner, the parameter of the resistance increase is substantially adjusted. That is, in the method of estimating the internal degradation state of the degraded cell, the parameters of the capacity decrease of the negative electrode NE, the capacity decrease of the positive electrode PE, and the decrease of lithium ions are changed and provisionally fixed, and in this state, the parameter of the resistance increase is adjusted. Therefore, the fitting unit 150 can set the changes of all the parameters that are factors in capacity degradation.

After the voltage fitting operation, the fitting unit 150 performs a fine adjustment fitting operation of finely adjusting a gap between the target charge curve 10 of the target battery OB and the reference charge curve 20 (the negative electrode QV curve 24, the positive electrode QV curve 22, and the full cell QV curve 26). As described above, even if the characteristic curves obtained by differentiating the current capacity with respect to the voltage together are fit to each other, there may be a slight gap on the charge curve represented by the current capacity and the voltage (the target charge curve 10 and the reference charge curve 20). Therefore, the fitting unit 150 performs the fine adjustment operation on a charge curve at the end to eliminate the slight gap.

The data obtained by the reference data acquisition process can be used as the full cell QV curve 26. The positive electrode QV curve 22 and the negative electrode QV curve 24 can be obtained by applying the division point DP of the characteristic curve (positive/negative electrode division point DP′) on the QV graph and dividing the reference charge curve 20. In other words, as shown in the right graph of FIG. 6, the reference charge curve 20a which is less than the positive/negative pole division point DP′ becomes the negative electrode QV curve 24, and the reference charge curve 20b which is equal to or more than the positive/negative electrode division point DP′ becomes the positive electrode QV curve 22. In the negative electrode QV curve 24, the voltage corresponding to the current capacity that is equal to or more than the positive/negative electrode division point DP′ may be a value that is obtained by extending the voltage of the positive/negative electrode division point DP′ in a constant manner (see a thin line in FIG. 6). Likewise, in the positive electrode QV curve 22, the voltage corresponding to the current capacity that is less than the positive/negative electrode division point DP′ may be a value that is obtained by extending the voltage of the positive/negative electrode division point DP′ in a constant manner (see a thin line (one dot chain line) in FIG. 6).

In the fine adjustment fitting operation, the fitting unit 150 may set an upper limit value and a lower limit value to each parameter of capacity degradation. In addition, regarding a region of the charge curve used for the fine adjustment fitting operation, the fitting unit 150 may use the entire current capacity=0 to 100%, and may divide the region into the low current capacity region used in the low current capacity side fitting operation and the high current capacity region used in the high current capacity side fitting operation.

The fitting unit 150 completes all the fitting operations by completion of the fine adjustment fitting operation. At the time of this completion, the fitting unit 150 stores in the memory unit 148 each parameter (the capacity decrease of the positive electrode PE, the capacity decrease of the negative electrode NE, the decrease of lithium ions, and the resistance increase) of capacity degradation that has changed because of each fitting operation. In addition, the information processing apparatus 144 informs, through the reporting means (monitor, etc.) (not shown), the user of each parameter of the capacity degradation analyzed. Accordingly, the user can recognize the state of capacity degradation of the target battery OB.

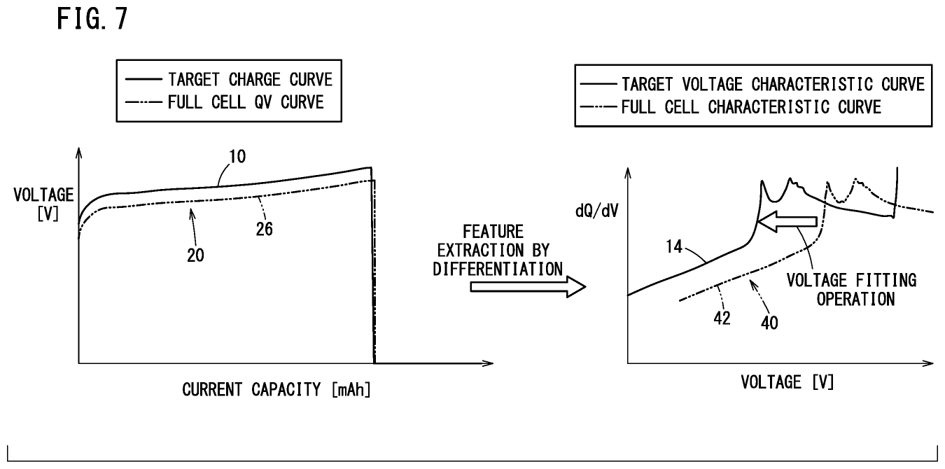

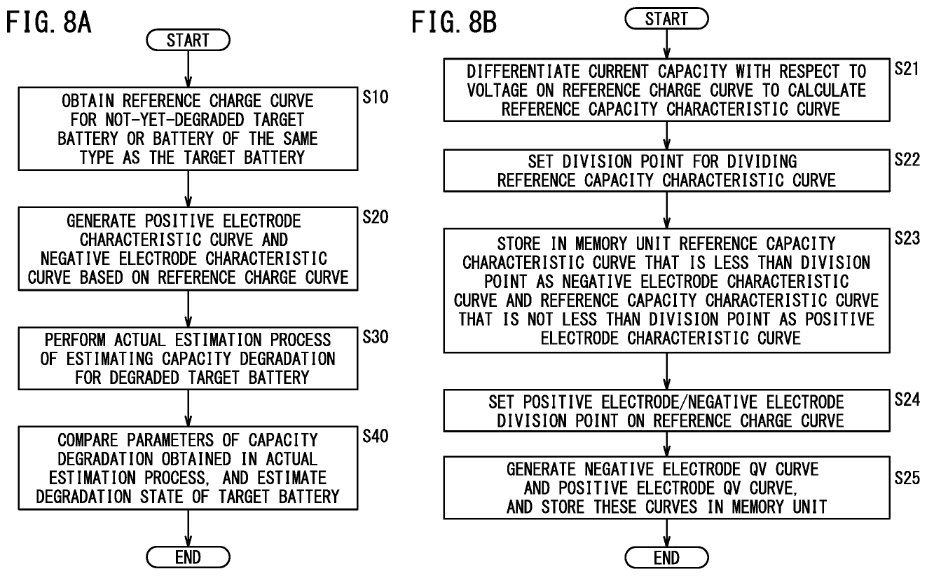

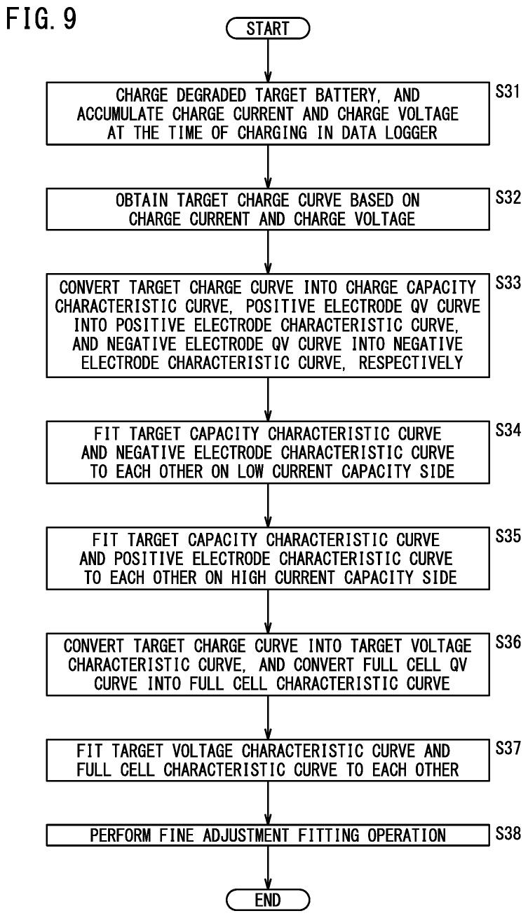

The measurement system 100 according to the embodiment of the present invention is basically constituted as described above. Hereinafter, the flow of the internal degradation state estimation method will be described with reference to FIGS. 8A to 9.

In the method of estimating the internal degradation state of the degraded cell, firstly, the reference data acquisition process is performed. Specifically, as shown in FIG. 8A, the measurement system 100 obtains the reference charge curve 20 for the not-yet-degraded target battery OB or a battery of the same type as the target battery OB, and stores the reference charge curve 20 in the memory unit 148 (step S10). For example, the measurement system 100 charges the not-yet-degraded target battery OB using the charger 120, accumulates in the data logger 142 the charge current and the charge voltage given at the time of the charging, and calculates the reference charge curve 20 based on the charge current and the charge voltage accumulated by the charge curve acquisition unit 146.

Thereafter, the reference data generation unit 152 of the information processing apparatus 144 generates, based on the obtained reference charge curve 20, the positive electrode characteristic curve 32 and the negative electrode characteristic curve 34 used as the reference data of the fitting operation (step S20). Further, at this time, the fitting unit 150 may generate the positive electrode QV curve 22 and the negative electrode QV curve 24 together.

Specifically, as shown in FIG. 8B, the reference data generation unit 152 takes the derivative of the current capacity with respect to the voltage on the reference charge curve 20 and calculates the reference capacity characteristic curve 30 represented by the current capacity and the derivative (step S21). Thereafter, on the reference capacity characteristic curve 30, the reference data generation unit 152 sets the division point DP that divides the reference capacity characteristic curve 30 (step S22). As described above, the division point DP is set at the predetermined position beyond the two peaks p1, p2 of the reference capacity characteristic curve 30 in the direction in which the current capacity increases (e.g., an inflection point CP in a region where the reference capacity characteristic curve 30 lowers beyond the higher peak p2). Then, the reference data generation unit 152 stores the reference capacity characteristic curve 30a, which is less than the division point DP, in the memory unit 148 as the negative electrode characteristic curve 34, and stores the reference capacity characteristic curve 30b, which is equal to or more than the division point DP, in the memory unit 148 as the positive electrode characteristic curve 32 (step S23).

Further, the reference data generation unit 152 sets the division point DP set on the reference capacity characteristic curve 30 as the positive/negative electrode division point DP′ on a not-yet-differentiated the reference charge curve 20 (step S24). The reference data generation unit 152 inverts the reference charge curve 20a, which is less than the positive/negative electrode division point DP′, in the voltage direction to generate the negative electrode QV curve 24, and generates the positive electrode QV curve 22 from the reference charge curve 20b, which is not less than the positive/negative electrode division point DP′, and stores these items of data in the memory unit 148 (step S25).

Further, in the internal degradation state estimation method, the actual estimation process of estimating the capacity degradation of the degraded target battery OB is performed (step S30). As shown in FIG. 9, in the actual estimation process, the measurement system 100 charges the degraded target battery OB with the charger 120, and accumulates in the data logger 142 the charge current and the charge voltage given at the time of the charging (step S31). Then, the charge curve acquisition unit 146 of the information processing apparatus 144 obtains the target charge curve 10 based on the accumulated charge current and the accumulated charge voltage (step S32). Thereafter, the fitting unit 150 of the information processing apparatus 144 performs a fitting operation of the target charge curve 10 and the reference charge curve 20.

In the fitting operation, the fitting unit 150 differentiates the current capacity of the target charge curve 10 with respect to the voltage and converts the target charge curve 10 into the target capacity characteristic curve 12 (step S33). Then, the fitting unit 150 extracts regions where a correlation is strong with respect to the target capacity characteristic curve 12, the positive electrode characteristic curve 32 (reference capacity characteristic curve 30b), and the negative electrode characteristic curve 34 (reference capacity characteristic curve 30a) and performs the fitting operation in the order of stronger correlations.

Specifically, the fitting unit 150 first performs the low current capacity side fitting operation of that fits the target capacity characteristic curve 12 and the negative electrode characteristic curve 34 to each other on the low current capacity side (where the current capacity is approximately in the range of 0% to 30%) (step S34). As a result, one of the target capacity characteristic curve 12 and the negative electrode characteristic curve 34 (e.g., the negative electrode characteristic curve 34) is moved in the derivative direction to eliminate a gap in the derivative direction. Then, by the low current capacity side fitting operation, the parameter of the capacity decrease of the negative electrode NE is changed.

Next, the fitting unit 150 performs the high current capacity side fitting operation that fits the target capacity characteristic curve 12 and the positive electrode characteristic curve 32 to each other on the high current capacity side (where the current capacity is approximately in the range of 80% to 100%) (step S35). As a result, one of the target capacity characteristic curve 12 and the positive electrode characteristic curve 32 (e.g., the positive electrode characteristic curve 32) is moved in the derivative direction and the current capacity direction to eliminate gaps in the derivative direction and the current capacity direction. Then, by the high current capacity side fitting operation, the parameter of the capacity decrease of the positive electrode PE and the decrease of lithium ions are changed.

Then, the fitting unit 150 converts the target charge curve 10 into the target voltage characteristic curve 14, and likewise, converts the reference charge curve 20 (full cell QV curve 26) into the reference voltage characteristic curve 40 (full cell characteristic curve 42) (step S36). Further, the fitting unit 150 performs the voltage fitting operation of fitting the target voltage characteristic curve 14 and the full cell characteristic curve 42 to each other (step S37). As a result, one of the target voltage characteristic curve 14 and the full cell characteristic curve 42 (e.g., the full cell characteristic curve 42) moves in the voltage direction to eliminate a gap in the voltage direction. Then, by the voltage fitting operation, the parameter of the resistance increase is changed.

At the end of the fitting operation, the fitting unit 150 performs a fine adjustment fitting operation (step S38). In the fine fitting operation, the fitting unit 150 eliminates a minute gap on the charge curves (the target charge curve 10 and the reference charge curve 20 (the positive electrode QV curve 22, the negative electrode QV curve 24, and the full cell QV curve 26)), thereby allowing the target charge curve 10 and the reference charge curve 20 to suitably fit to each other.

After the above actual estimation process is finished, the information processing apparatus 144 estimates the degradation state of the target battery OB based on the parameters of the capacity degradation obtained through the actual estimation process, and informs the information by suitable reporting means (step S40). As a result, when the user looks at the estimation result reported by the information processing apparatus 144, the user can accurately recognize the degradation state of the degraded target battery OB.

The present invention is not limited to the above embodiment, and various modification can be made in line with the gist of the present invention. For example, in the internal degradation state estimation method of the degraded cell according to the embodiment of the present invention, the fitting operation on the low current capacity side where the correlation is strong on the characteristic curves is first performed. However, in the internal degradation state estimation method, in the case where the correlation of the characteristic curves on the high current capacity side is stronger than the low current capacity side, the fitting operation on the high current capacity side is first performed.

Further, in the fitting operation, the fitting unit 150 is not limited to the method of fitting the characteristic curves formed by differentiating the charge curves (the target charge curve 10 and the reference charge curve 20). A method of fitting the charge curves to each other may be adopted. In this case, the positive electrode QV curve 22 and the negative electrode QV curve 24 used as the reference data of the fitting may be generated according to the method as described above. Alternatively, the positive electrode QV curve 22 may be obtained by integrating the reference capacity characteristic curve 30b that is equal to or more than the division point DP. Likewise, the negative electrode QV curve 24 may be obtained by integrating the reference capacity characteristic curve 30a that is less than the division point DP.

The low current capacity side fitting operation (fitting of the target capacity characteristic curve 12 and the negative electrode characteristic curve 34) and the high current capacity side fitting operation (fitting of the target capacity characteristic curve 12 and the positive electrode characteristic curve 32) do not have to be performed only once. For example, after the low current capacity side fitting operation, the high current capacity side fitting operation may be performed, and thereafter, the low current capacity side fitting operation may be performed again. Alternatively, after the high current capacity side fitting operation, the low current capacity side fitting operation may be performed, and thereafter, the high current capacity side fitting operation may be performed again. In this manner, by performing the low current capacity side fitting operation and the high current capacity side fitting operation alternately multiple times, it is possible to improve the fitting accuracy.

The technical concept and advantages understood from the above embodiment will be described below.

According to a first aspect of the present invention, a method of estimating an internal degradation state of a degraded cell is provided. The method includes obtaining the reference charge curve 20 represented by the current capacity and the voltage for the not-yet-degraded target battery OB or a battery of the same type as the target battery OB, calculating the reference capacity characteristic curve 30 represented by the current capacity and a derivative by differentiating the current capacity by the voltage on the reference charge curve 20, dividing the reference capacity characteristic curve 30 at the division point DP given in the current capacity direction, and setting the reference capacity characteristic curve 30a, which is less than the division point DP, to a negative electrode component (negative electrode characteristic curve 34) and setting the reference capacity characteristic curve 30b, which is not less than the division point DP, to a positive electrode component (positive electrode characteristic curve 32), obtaining the target charge curve represented by the current capacity and the voltage for the degraded target battery OB, calculating the target capacity characteristic curve 12 represented by the current capacity and the differential value by differentiating the current capacity by the voltage on the target charge curve 10, and estimating capacity degradation of the target battery by obtaining changes of a plurality of types of parameters based on the fitting operation that fits each of the negative electrode component and the positive electrode component of the reference capacity characteristic curve 30 and the target capacity characteristic curve 12.

According to the method of estimating the internal degradation state of the degraded cell as described above, it is possible to easily obtain the reference data (negative electrode component (negative electrode characteristic curve 34) and the positive electrode component (positive electrode characteristic curve 32) of the reference capacity characteristic curve 30) for estimating the capacity degradation of the target battery OB without performing a destructive inspection of the secondary battery. Further, in the internal degradation state estimation method, by performing a fitting operation of the reference data and the target capacity characteristic curve 12 of the target battery OB, it is possible to suitably estimate the capacity degradation of the target battery OB.

Further, the low current capacity side of the reference capacity characteristic curve 30 has a plurality of peaks p1, p2 in the direction in which the derivative increases. The division point DP is set at the peak p2, which is higher between the plurality of peaks p1, p2 in the direction in which the current capacity increases, or is set in a predetermined range beyond the higher peak p2. By setting the division point DP in this manner, the internal degradation state estimation method can accurately extract the negative electrode component (negative electrode characteristic curve 34) that has a plurality of peaks p1, p2 on the low current capacity side of the reference capacity characteristic curve 30.

Further, in the reference capacity characteristic curve 30, the derivative decreases from the higher peak p2 toward the direction in which the current capacity increases, and the division point DP is set at an inflection point (CP) where the decrease rate of the derivative changes. In this manner, it is possible to reliably divide the negative electrode component (negative electrode characteristic curve 34) and the positive electrode component (positive electrode characteristic curve 32) of the reference capacity characteristic curve 30.

Further, the fitting operation performs a low current capacity side fitting operation of fitting the target capacity characteristic curve 12 and the negative electrode component (negative electrode characteristic curve 34) of the reference capacity characteristic curve 30 having a stronger correlation with the target capacity characteristic curve 12, and thereafter, performs a high current capacity side fitting operation of fitting the target capacity characteristic curve 12 and the positive electrode component (positive electrode characteristic curve 32) of the reference capacity characteristic curve 30 having a weaker correlation with the target capacity characteristic curve 12. In this manner, in the internal degradation state estimation method, by performing the fitting operation in the order of the low current capacity side and the high current capacity side, it is possible to suitably extract changes of the parameters of the capacity decrease of the negative electrode NE, the capacity decrease of the positive electrode PE, and the decrease of lithium ions among the plurality of types of parameters.

Further, the current capacity is differentiated by the voltage on the target charge curve 10 to calculate the target voltage characteristic curve 14 represented by the voltage and the derivative, and in the fitting operation, after the reference capacity characteristic curve 30 and the target capacity characteristic curve 12 are fitted to each other, the voltage fitting operation is performed that fits the target voltage characteristic curve 14 and the reference voltage characteristic curve 40 formed by differentiating the current capacity by the voltage on the reference charge curve 20. In this manner, in the internal degradation state estimation method, it is possible to stably extract the parameter of the voltage offset due to the resistance increase.

Further, the division point DP set on the reference capacity characteristic curve 30 is applied to a positive/negative electrode division point DP′ that divides the reference charge curve 20 to generate a negative electrode QV curve 24 from the reference charge curve 20a, which is less than the positive/negative electrode division point DP′, and generate a positive electrode QV curve 22 from the reference charge curve 20b, which is equal to or more than the positive/electrode division point DP′. In this manner, the internal degradation state estimation method can use the positive electrode QV curve 22 and the negative electrode QV curve 24 as the reference data.

Further, in the fitting operation, after the voltage fitting operation, the fine adjustment fitting operation of fitting the negative electrode QV curve 24 and the positive electrode QV curve 22 and the target charge curve 10 by fine adjustment is performed. In this manner, even if a minute gap is produced by the fitting operation using the characteristic curves, the internal degradation state estimation method can eliminate such a gap by the fine adjustment fitting operation. Accordingly, it becomes possible to estimate capacity degradation of the target battery OB with a higher degree of accuracy.

Further, according to a second aspect of the present invention, the measurement system 100 performs a method of estimating an internal degradation state of a degraded cell is provided. The measurement system 100 includes the charger 120 that charges the target battery OB or a battery of the same type as the target battery OB, and the estimation apparatus 140 connected to the charger 120. The estimation apparatus 140 obtains the reference charge curve 20 represented by the current capacity and the voltage based on charge current and charge voltage supplied to the target battery OB or the battery of the same type as the target battery OB, calculates the reference capacity characteristic curve 30 represented by the current capacity and a differential value by differentiating the current capacity by the voltage on the reference charge curve 20, divide the reference capacity characteristic curve 30 at the division point DP given in the current capacity direction, and set the reference capacity characteristic curve 30a, which is less than the division point DP, to a negative electrode component (negative electrode characteristic curve 34) and set the reference capacity characteristic curve 30b, which is equal to or more than the division point DP, to a positive electrode component (positive electrode characteristic curve 32), obtain the target charge curve 10 represented by the current capacity and the voltage based on the charge current and the charge voltage for the degraded target battery OB, calculate the target capacity characteristic curve 12 represented by the current capacity and the derivative by differentiating the current capacity by the voltage on the target charge curve 10, and estimate capacity degradation of the target battery OB by obtaining changes of a plurality of types of parameters based on a fitting operation that fits the target capacity characteristic curve 12 and each of the negative electrode component and the positive electrode component of the reference capacity characteristic curve 30. In the structure, in the measurement system 100, it is possible to easily obtain the reference data without performing a destructive inspection of the secondary battery and suitably estimate the capacity degradation of the target battery OB using this reference data.

What is claimed is:

1. A method of estimating an internal degradation state of a degraded cell, the method comprising:
obtaining a reference charge curve represented by current capacity and voltage for a not-yet-degraded target battery or a battery of the same type as the target battery;
calculating a reference capacity characteristic curve represented by the current capacity and a derivative by differentiating the current capacity with respect to the voltage on the reference charge curve;
dividing the reference capacity characteristic curve at a division point given in the current capacity direction, and setting the reference capacity characteristic curve that is less than the division point to a negative electrode component and setting the reference capacity characteristic curve that is equal to or more than the division point to a positive electrode component;
obtaining a target charge curve represented by the current capacity and the voltage for degraded the target battery;
calculating a target capacity characteristic curve represented by the current capacity and the derivative by differentiating the current capacity with respect to the voltage on the target charge curve; and
estimating capacity degradation of the target battery by obtaining changes of a plurality of types of parameters based on a fitting operation that fits each of the negative electrode component and the positive electrode component of the reference capacity characteristic curve and the target capacity characteristic curve.

2. The method according to claim 1,
wherein the reference capacity characteristic curve on a low current capacity side has a plurality of peaks in a direction in which the derivative increases; and
the division point is set at a peak that is higher among the plurality of peaks in a direction in which the current capacity increases or is set in a predetermined range beyond the higher peak.

3. The method according to claim 2, wherein in the reference capacity characteristic curve, the derivative decreases from the higher peak toward the direction in which the current capacity increases, and the division point is set at an inflection point where a decrease rate of the derivative changes.

4. The method according to claim 1,
wherein the fitting operation includes:
a low current capacity side fitting operation of fitting the target capacity characteristic curve and the negative electrode component of the reference capacity characteristic curve having a stronger correlation with the target capacity characteristic curve; and
a high current capacity side fitting operation of fitting, after the low current capacity side fitting operation, the target capacity characteristic curve and the positive electrode component of the reference capacity characteristic curve having a weaker correlation with the target capacity characteristic curve.

5. The method according to claim 4,
wherein the current capacity is differentiated with respect to the voltage on the target charge curve to calculate a target voltage characteristic curve represented by the voltage and the differential value; and
in the fitting operation, after the reference capacity characteristic curve and the target capacity characteristic curve are fitted to each other, a voltage fitting operation is performed that fits the target voltage characteristic curve and a reference voltage characteristic curve that is formed by differentiating the current capacity with respect to the voltage on the reference charge curve.

6. The method according to claim 5,
wherein, the division point set on the reference capacity characteristic curve is applied to a positive/negative electrode division point that divides the reference charge curve, whereby a negative electrode QV curve is generated from the reference charge curve that is less than the positive/negative electrode division point and a positive electrode QV curve is generated from the reference charge curve that is equal to or more than the positive/electrode division point.

7. The method according to claim 6, wherein in the fitting operation, after the voltage fitting operation is performed, a fine adjustment fitting operation is performed that fits the target charge curve and the negative electrode QV curve and the positive QV curve by fine adjustment.

8. A measurement system that performs a method of estimating an internal degradation state of a degraded cell, the measurement system comprising:
a charger that charges a target battery or a battery of the same type as the target battery; and
an estimation apparatus connected to the charger,
wherein the estimation apparatus is configured to:
obtain a reference charge curve represented by current capacity and voltage based on charge current and charge voltage supplied to the target battery or the battery of the same type as the target battery;
calculate a reference capacity characteristic curve represented by the current capacity and a derivative by differentiating the current capacity with respect to the voltage on the reference charge curve;
divide the reference capacity characteristic curve at a division point given in a current capacity direction, and set the reference capacity characteristic curve that is less than the division point to a negative electrode component and set the reference capacity characteristic curve that is equal to or more than the division point to a positive electrode component;
obtain a target charge curve represented by the current capacity and the voltage based on charge current and charge voltage supplied to a degraded target battery;
calculate a target capacity characteristic curve represented by the current capacity and the derivative by differentiating the current capacity with respect to the voltage for the target charge curve; and
estimate capacity degradation of the target battery by obtaining changes of a plurality of types of parameters based on a fitting operation that fits each of the negative electrode component and the positive electrode component of the reference capacity characteristic curve and the target capacity characteristic curve.
